(19) United States
(12) Patent Application Publication
(10) Pub. No.: US 2026/0173432 A1
(43) Pub. Date: Jun. 18, 2026

(54) NITRIDE SEMICONDUCTOR DEVICE

(71) Applicant: Panasonic Holdings Corporation, Osaka (JP)

(72) Inventors: Masahiro OGAWA, Osaka (JP); Satoshi TAMURA, Osaka (JP); Daisuke SHIBATA, Kyoto (JP)

(21) Appl. No.: 19/529,714

(22) Filed: Feb. 4, 2026

Related U.S. Application Data
(63) Continuation of application No. PCT/JP2024/035702, filed on Oct. 4, 2024.

(30) Foreign Application Priority Data
Oct. 10, 2023 (JP) 2023-175573

(51) Int. Cl. H10D 30/47; H10D 62/17; H10D 62/824

(52) U.S. Cl. CPC H10D 30/477; H10D 30/478; H10D 62/328; H10D 62/824

(57) ABSTRACT

A nitride semiconductor device includes: a substrate; a first nitride semiconductor layer above the substrate; and a second nitride semiconductor layer covering a trench provided in the first nitride semiconductor layer. When a location of the trench where the trench extends in a first direction parallel to an off-direction of the substrate is defined as a first location, and a location of the trench where the trench extends in a second direction perpendicular to the off-direction of the substrate is defined as a second location, a cross-sectional area, orthogonal to the second direction, of the trench at the second location is smaller than a cross-sectional area, orthogonal to the first direction, of the trench at the first location.

### CROSS REFERENCE TO RELATED APPLICATIONS

This is a continuation application of PCT International Application No. PCT/JP 2024/035702 filed on Oct. 4, 2024, designating the United States of America, which is based on and claims priority of Japanese Patent Application No. 2023-175573 filed on Oct. 10, 2023. The entire disclosures of the above-identified applications, including the specifications, drawings and claims are incorporated herein by reference in their entirety.

Field

The present disclosure relates to a nitride semiconductor device.

### BACKGROUND

Nitride semiconductors, such as gallium nitride (GaN), are wide band-gap semiconductors with a high dielectric breakdown field, and have the property of a higher saturation drift velocity of electrons compared to, for example, gallium arsenide (GaAs) semiconductors or silicon (Si) semiconductors. Accordingly, research and development are currently underway on power transistors using nitride semiconductors that are advantageous for achieving higher output and higher breakdown voltage.

For instance, Patent Literature (PTL) 1 discloses a semiconductor device including a GaN-based layered structure. The semiconductor device disclosed in PTL 1 is a vertical field-effect transistor (FET) including (i) a regrowth layer including an electron transport layer and an electron supply layer that are located to cover an opening formed in the GaN-based layered structure and (ii) a gate electrode formed along and on the regrowth layer. Two-dimensional electron gas (2DEG) generated in the regrowth layer forms a channel, enabling the realization of an FET with high electron mobility and low on-resistance.

### CITATION LIST

### Patent Literature

PTL 1: Japanese U.S. Pat. No. 7,017,579

### SUMMARY

### Technical Problem

In a field-effect transistor having a trench, such as a gate opening, during the trench-filling regrowth, abnormal growth may occur in an off-direction of a substrate.

In view of this, the present disclosure provides a nitride semiconductor device with suppressed abnormal growth.

### Solution to Problem

A nitride semiconductor device according to one aspect of the present disclosure includes: a substrate; a first nitride semiconductor layer above the substrate; and a second nitride semiconductor layer covering a trench provided in the first nitride semiconductor layer. When a location of the trench where the trench extends in a first direction parallel to an off-direction of the substrate is defined as a first location, and a location of the trench where the trench extends in a second direction perpendicular to the off-direction of the substrate is defined as a second location, a cross-sectional area, orthogonal to the second direction, of the trench at the second location is smaller than a cross-sectional area, orthogonal to the first direction, of the trench at the first location.

### Advantageous Effects

The present disclosure can provide a nitride semiconductor device with suppressed abnormal growth.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a nitride semiconductor device according to an embodiment.

FIG. 2 is a plan view illustrating a plan view layout of the nitride semiconductor device according to the embodiment.

FIG. 3 is a plan view for explaining abnormal growth caused by the off-angle of a substrate in a nitride semiconductor device according to a comparison example.

FIG. 4 is an enlarged plan view illustrating a shape of a gate opening in area IV in FIG. 2.

FIG. 5 is a plan view illustrating a plan view layout of a nitride semiconductor device according to a variation of the embodiment.

FIG. 6 is an enlarged plan view illustrating a shape of a gate opening in area VI in FIG. 5.

FIG. 7A is a cross-sectional view illustrating a nitride semiconductor layering process in a fabrication method for fabricating the nitride semiconductor device according to the embodiment.

FIG. 7B is a cross-sectional view illustrating a resist patterning process in the fabrication method for fabricating the nitride semiconductor device according to the embodiment.

FIG. 7C is a cross-sectional view illustrating a gate opening formation process in the fabrication method for fabricating the nitride semiconductor device according to the embodiment.

FIG. 7D is a cross-sectional view illustrating a nitride semiconductor regrowth process in the fabrication method for fabricating the nitride semiconductor device according to the embodiment.

FIG. 7E is a cross-sectional view illustrating a gate electrode formation process in the fabrication method for fabricating the nitride semiconductor device according to the embodiment.

FIG. 7F is a cross-sectional view illustrating a source electrode formation process in the fabrication method for fabricating the nitride semiconductor device according to the embodiment.

### DESCRIPTION OF EMBODIMENT

### Overview of Present Disclosure

The inventors have found that the conventional semiconductor device described in the Background section has the following issues.

A conventional semiconductor device includes a substrate with an off-angle. The off-angle is an angle formed by a main surface of the substrate and a crystal plane (specifically, the c-plane). In conventional semiconductor devices, an abnormal growth area caused by the off-angle of a substrate is seen in an area adjacent to a gate opening. Specifically, abnormal growth occurs in a semiconductor layer provided to cover the gate opening, and a region with a reduced film thickness is generated on the lower side in the off direction of the substrate.

In view of this, the present disclosure provides a nitride semiconductor device with suppressed abnormal growth.

A nitride semiconductor device according to a first aspect of the present disclosure includes: a substrate; a first nitride semiconductor layer above the substrate; and a second nitride semiconductor layer covering a trench provided in the first nitride semiconductor layer. When a location of the trench where the trench extends in a first direction parallel to an off-direction of the substrate is defined as a first location, and a location of the trench where the trench extends in a second direction perpendicular to the off-direction of the substrate is defined as a second location, a cross-sectional area, orthogonal to the second direction, of the trench at the second location is smaller than a cross-sectional area, orthogonal to the first direction, of the trench at the first location.

This can expedite trench filling during the regrowth, which can suppress abnormal growth.

A nitride semiconductor device according to a second aspect of the present disclosure is the nitride semiconductor device according to the first aspect in which a width of the trench at the second location is less than a width of the trench at the first location.

The width of the trench can be easily and accurately adjusted by, for example, the shape of an etching mask used for trench formation. This makes it easier to perform trench filling during the regrowth as expected. Thus, the suppression effects of abnormal growth can be enhanced.

A nitride semiconductor device according to a third aspect of the present disclosure is the nitride semiconductor device according to the first or second aspect in which the trench is an annular trench.

If the trench has terminal end portions, abnormal growth tends to occur in the terminal end portions. Since an annular trench does not have terminal end portions, abnormal growth can be suppressed.

A nitride semiconductor device according to a fourth aspect of the present disclosure is the nitride semiconductor device according to any one of the first to third aspects in which the first nitride semiconductor layer includes: a third nitride semiconductor layer of a first conductivity type; and a fourth nitride semiconductor layer that is above the third nitride semiconductor layer, and has a second conductivity type with a polarity opposite to the first conductivity type.

Thus, a p-n junction between the third nitride semiconductor layer and the fourth nitride semiconductor layer can form a depletion layer near the interface. For instance, when the nitride semiconductor device is caused to function as a device that passes current in a vertical direction of the substrate, leakage current can be suppressed by the depletion layer. Thus, it is possible to improve the breakdown voltage of the device.

A nitride semiconductor device according to a fifth aspect of the present disclosure is the nitride semiconductor device according to the fourth aspect that includes a gate electrode above the second nitride semiconductor layer, the gate electrode overlapping the first location in a plan view of the substrate; a source electrode that is above the substrate and is spaced apart from the gate electrode; and a drain electrode below the substrate, in which the trench penetrates the fourth nitride semiconductor layer, and the second nitride semiconductor layer is in contact with the third nitride semiconductor layer on a bottom of the trench.

Thus, a vertical FET can be embodied. It should be noted that the vertical FET is a FET where a direction in which drain current flows is mainly a direction perpendicular to a main surface of the substrate. Moreover, since a depletion layer can be formed near the interface between the third nitride semiconductor layer and the fourth nitride semiconductor layer, it is possible to suppress the occurrence of leakage current between the source electrode and the drain electrode. Thus, a vertical FET with a high breakdown voltage can be embodied.

A nitride semiconductor device according to a sixth aspect of the present disclosure is the nitride semiconductor device according to the fifth aspect in which the source electrode is in contact with the fourth nitride semiconductor layer on a bottom of an opening penetrating the second nitride semiconductor layer.

Thus, it is possible to supply source electric potential to the fourth nitride semiconductor layer. Stabilized electric potential of the fourth nitride semiconductor layer can enhance the off-characteristics of the vertical FET. For instance, because of a voltage applied between the source electrode and the drain electrode, a depletion layer can be formed near the interface between the third nitride semiconductor layer and the fourth nitride semiconductor layer. By forming the depletion layer, it is possible to suppress the occurrence of leakage current between the source and drain, which can improve the breakdown voltage of the nitride semiconductor device.

A nitride semiconductor device according to a seventh aspect of the present disclosure is the nitride semiconductor device according to the fifth or sixth aspect in which the source electrode is elongated in the first direction in the plan view of the substrate.

Since wasted space in a plan view layout can be reduced, the nitride semiconductor device can be miniaturized.

A nitride semiconductor device according to an eighth aspect of the present disclosure is the nitride semiconductor device according to the seventh aspect in which the trench includes: two linear portions interposing the source electrode and extending in the first direction; a first connection portion of an arch shape connecting first end portions in the first direction respectively included in the two linear portions; and a second connection portion of an arch shape connecting second end portions respectively included in the two linear portions that are on an opposite side from the first end portions, each of the two linear portions includes the first location, and each of the first connection portion and the second connection portion includes the second location.

Thus, an annular trench is formed by connecting both end portions of the two linear portions using the first connection portion and the second connection portion. Since the annular trench does not have terminal end portions, abnormal growth can be suppressed, which can suppress leakage current. It should be noted that in a plan view, if the outline of the trench is polyline-like, vertices serve as singular points, and abnormal growth is likely to occur. In the nitride semiconductor device according to the aspect, each of the first connection portion and the second connection portion is curved into an arch shape. Thus, it is possible to suppress the occurrence of singular points in abnormal growth.

A nitride semiconductor device according to a ninth aspect of the present disclosure is the nitride semiconductor device according to the eighth aspect in which a width of the first connection portion monotonously increases from the second location included in the first connection portion to the first end portions, and a width of the second connection portion monotonously increases from the second location included in the second connection portion to the second end portions.

Thus, it is possible to suppress an abrupt change in the width of the trench, which can suppress the occurrence of singular points in abnormal growth.

A nitride semiconductor device according to a tenth aspect of the present disclosure is the nitride semiconductor device according to the eighth aspect in which each of the first connection portion and the second connection portion has a uniform width.

Thus, it is possible to uniformly reduce the width across the entire area of each of the first connection portion and the second connection portion, which can reduce an abnormal growth area.

A nitride semiconductor device according to an eleventh aspect of the present disclosure is the nitride semiconductor device according to any one of the eighth to tenth aspects in which the first location is a location where the trench intersects a first virtual straight line passing through a center of the source electrode in the plan view of the substrate and extending in the second direction, and the second location is a location where the trench intersects a second virtual straight line passing through the center of the source electrode in the plan view of the substrate and extending in the first direction.

A nitride semiconductor device according to a twelfth aspect of the present disclosure is the nitride semiconductor device according to any one of the eighth to eleventh aspects that includes three or more source electrodes each of which is the source electrode, in which two or more trenches each of which is the trench are arranged in the second direction, the three or more source electrodes are arranged in the second direction, and a corresponding one of the three or more source electrodes is disposed between adjacent trenches among the two or more trenches.

Thus, the distance between adjacent source and gate electrodes can be decreased easily. Since channels with short channel lengths can be formed within the plane, higher output of the nitride semiconductor device can be achieved.

A nitride semiconductor device according to a thirteenth aspect of the present disclosure is the nitride semiconductor device according to any one of the first to twelfth aspects in which the second nitride semiconductor layer includes a layered structure of a GaN layer and an AlGaN layer.

Thus, two-dimensional electron gas generated near the heterointerface between the AlGaN layer and the GaN layer can be used as a current path, which can reduce the resistance of the current path.

Hereinafter, an embodiment is described in detail with reference to the drawings.

It should be noted that the embodiments described below each indicate a general or specific example. The numerical values, shapes, materials, elements, arrangement and connection of the elements, steps, order of steps, and so forth indicated in the embodiments described below are merely examples, and do not intend to limit the present disclosure. Moreover, among elements described in the embodiments below, those not recited in the independent claims are described as optional elements.

Moreover, the figures are schematic illustrations and are not necessarily precise depictions. Accordingly, for instance, scales used in the figures need not necessarily be the same. Moreover, in the figures, substantially the same elements are assigned the same reference signs, and overlapping explanations are omitted or simplified.

Moreover, in the specification, terms indicating relationships between elements, such as parallel or perpendicular, terms describing the shapes of elements, such as rectangular or circular, and numerical ranges should not be construed as limited to their strict interpretation. Rather, they are intended to encompass substantially equivalent ranges, including variations of, for example, approximately a few percent.

Moreover, in the specification, the terms “above” and “below” do not indicate the upward direction (vertically upward) or the downward direction (vertically downward) in absolute spatial recognition, and are used as terms determined by a relative positional relationship based on the stacking order in a layered structure. Furthermore, the terms “above” and “below” apply not only when two elements are spaced apart from each other with another element present between the two elements, but also when the two elements are disposed in close contact with each other.

Moreover, in the specification and drawings, the X-axis, the Y-axis, and the Z-axis indicate three axes in a three-dimensional orthogonal coordinate system. When a substrate is rectangular in a plan view, the X-axis and the Y-axis respectively correspond to a direction parallel to a first side of a rectangle and a direction parallel to a second side and orthogonal to the first side. The Z-axis corresponds to a thickness direction of the substrate. It should be noted that in the specification, the thickness direction of the substrate is a direction perpendicular to a main surface of the substrate. The thickness direction is the same as a direction in which semiconductor layers are stacked, and is also referred to as a vertical direction. Moreover, a direction parallel to the main surface of the substrate may be referred to as a horizontal direction.

Moreover, the side on which a gate electrode and a source electrode are provided, relative to the substrate is regarded as above or the upper side, and the side on which a drain electrode is provided, relative to the substrate is regarded as below or the lower side.

Moreover, in the specification, unless explicitly stated otherwise, the term, “in a/the plan view” means that a nitride semiconductor device is viewed in a direction perpendicular to the main surface of the substrate of the nitride semiconductor device, that is, the main surface of the substrate is viewed from front.

Moreover, in the specification, a location of a trench means a point of a trench. A direction in which the trench extends is a direction in which a center line of the trench extends in the plan view. When the center line is curved, the direction in which the trench extends is defined as a tangential direction to the center line. The center line is a line continuously connecting center points across the width of the trench along its length. In the plan view, the width of the trench at a location is expressed as the distance (that is, the length of a line segment) between the intersection with the outline on the inner-circumferential side of the trench and the intersection with the outline on the outer-circumferential side of the trench, of the straight line, among innumerable straight lines passing through the location (namely, a single point) within the trench, for which the distance between the intersections is the shortest.

Moreover, in the specification, ordinal numbers, such as “first” and “second”, are used for the purpose of distinguishing between similar elements to avoid confusion, and do not indicate the quantity or order of the elements unless explicitly stated otherwise.

Moreover, in the specification, AlGaN means a ternary mixed crystal, AlₓGa₁₋ₓN (0<x<1). Hereinafter, multicomponent mixed crystals are abbreviated by an arrangement of their constituent element symbols, such as AlInN and GaInN. For instance, AlₓGa_{1-x-y}In_{y}N (0<x<1, 0<y<1, and 0<x+y<1), which is an example of a nitride semiconductor, is abbreviated as AlGaInN.

### EMBODIMENT

### Configuration

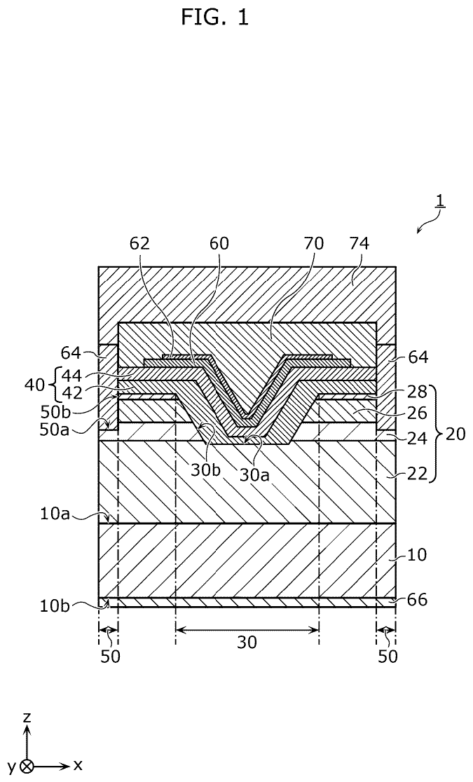

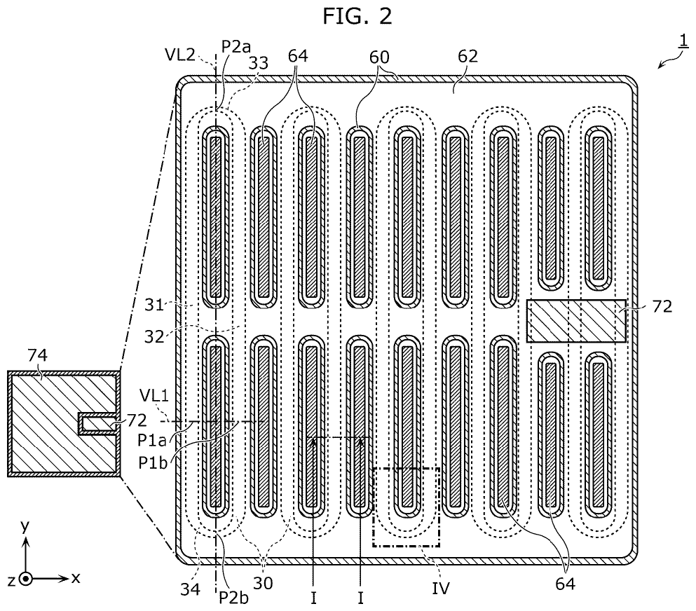

First, a configuration of a nitride semiconductor device according to an embodiment is described with reference to FIGS. 1 and 2. FIG. 1 is a cross-sectional view of nitride semiconductor device 1 according to the embodiment. FIG. 2 is a plan view illustrating a plan view layout of nitride semiconductor device 1 according to the embodiment. Here, FIG. 1 illustrates a cross-section of nitride semiconductor device 1 according to the embodiment taken along I-I line in FIG. 2.

In the embodiment, nitride semiconductor device 1 is a device having a layered structure of semiconductor layers containing, as main components, nitride semiconductors, such as GaN and AlGaN. Specifically, nitride semiconductor device 1 has a heterostructure of an AlGaN film and a GaN film.

In the heterostructure of the AlGaN film and the GaN film, spontaneous polarization or piezoelectric polarization on a c-plane referred to as the (0001) plane generates high-concentration two-dimensional electron gas (2DEG) on the heterointerface. Thus, even in an undoped state, the nitride semiconductor device has the feature that a sheet carrier concentration higher than or equal to 1×10¹³ cm⁻² is obtained on the heterointerface.

As illustrated in FIG. 1, nitride semiconductor device 1 includes substrate 10, first nitride semiconductor layer 20, and second nitride semiconductor layer 40. Nitride semiconductor device 1 further includes threshold control layer 60, gate electrode 62, source electrode 64, drain electrode 66, and insulation layer 70. Furthermore, as illustrated in FIG. 2, nitride semiconductor device 1 includes gate electrode pad 72 and source electrode pad 74.

Hereinafter, the elements of nitride semiconductor device 1 are described in detail.

Substrate 10 is made of a nitride semiconductor and includes first main surface 10a and second main surface 10b opposite to each other. First main surface 10a is the main surface on the side where drift layer 22 is formed, and corresponds to the top surface or front surface of substrate 10. Specifically, first main surface 10a has a predetermined off-angle relative to the c-plane. Second main surface 10b is the main surface on the side where drain electrode 66 is formed, and corresponds to the bottom surface or back surface of substrate 10.

Substrate 10 is, for example, an n-type GaN substrate having a thickness of 300 μm and a carrier concentration of 1×10¹⁸ cm⁻³. It should be noted that n-type and p-type indicate semiconductor conductivity types. In the embodiment, n-type is an example of a first conductivity type of a nitride semiconductor. P-type is an example of a second conductivity type with a polarity different from that of the first conductivity type.

First nitride semiconductor layer 20 is provided above substrate 10. As illustrated in FIG. 1, first nitride semiconductor layer 20 includes drift layer 22, first underlayer 24, second underlayer 26, and third underlayer 28. Moreover, gate opening 30 is provided in first nitride semiconductor layer 20.

Drift layer 22 is an example of a third nitride semiconductor layer of the first conductivity type provided above first main surface 10a of substrate 10. Drift layer 22 is, for instance, an n-type GaN film having a thickness of 8 μm and a carrier concentration of 1×10¹⁶ cm⁻³. Drift layer 22 is provided in contact with first main surface 10a of substrate 10.

First underlayer 24 is an example of a fourth nitride semiconductor layer of the second conductivity type provided above drift layer 22. First underlayer 24 is, for example, a p-type GaN film having a thickness of 400 nm and a carrier concentration of 1×10¹⁷ cm⁻³. First underlayer 24 is provided in contact with the top surface of drift layer 22.

First underlayer 24 suppresses leakage current between source electrode 64 and drain electrode 66. When for instance a reverse voltage is applied to a p-n junction formed by first underlayer 24 and drift layer 22, specifically, when the electric potential of drain electrode 66 becomes higher than that of source electrode 64, a depletion layer expands in drift layer 22. Thus, higher breakdown voltage can be achieved in nitride semiconductor device 1.

Second underlayer 26 is provided above first underlayer 24. Second underlayer 26 is formed of an insulating or semi-insulating nitride semiconductor. Second underlayer 26 is, for example, an undoped GaN film having a thickness of 200 nm. Second underlayer 26 is provided in contact with first underlayer 24.

It should be noted that the term “undoped”, as used here, means that the layer is not doped with a dopant, such as silicon (Si) or magnesium (Mg), that changes the polarity of GaN to the n-type or the p-type. In the embodiment, second underlayer 26 is doped with carbon. Specifically, second underlayer 26 has a carbon concentration higher than that of first underlayer 24.

Moreover, second underlayer 26 may contain silicon (Si) or oxygen (O) that was incorporated into second underlayer 26 during the film formation. In this case, although the carbon concentration of second underlayer 26 is, for example, higher than or equal to 3×10¹⁷ cm⁻³, it may be higher than or equal to 1×10¹⁸ cm⁻³. Although the silicon concentration or the oxygen concentration of second underlayer 26 is, for example, lower than or equal to 5×10¹⁶ cm⁻³, it may be lower than or equal to 2×10¹⁶ cm⁻³.

Here, if nitride semiconductor device 1 does not include second underlayer 26, a layered structure including: n-type electron supply layer 44 and electron transport layer 42; p-type first underlayer 24; and n-type drift layer 22 is formed between source electrode 64 and drain electrode 66. The layered structure serves as a parasitic bipolar transistor having a parasitic NPN structure.

During the off-state of nitride semiconductor device 1, when current flows through first underlayer 24, the parasitic bipolar transistor may be switched on, which may decrease the breakdown voltage of nitride semiconductor device 1. In this case, erroneous operation of nitride semiconductor device 1 tends to occur.

Second underlayer 26 suppresses the parasitic NPN structure from being formed. Thus, it is possible to decrease the erroneous operation of nitride semiconductor device 1 due to the formation of the parasitic NPN structure. It should be noted that if current flowing through first underlayer 24 is sufficiently suppressed, nitride semiconductor device 1 need not include second underlayer 26.

Third underlayer 28 is provided above second underlayer 26. Third underlayer 28 is, for example, an Al_{0.2}Ga_{0.8}N film having a thickness of 20 nm. Third underlayer 28 is provided in contact with second underlayer 26.

Third underlayer 28 suppresses a p-type impurity, such as Mg, from spreading from first underlayer 24. If Mg spreads into a channel in electron transport layer 42, the carrier concentration of two-dimensional electron gas may decrease, which may increase the on-resistance. It should be noted that the spread degree of Mg differs also depending on, for example, epitaxial growth conditions. Thus, if the spread of Mg is suppressed, nitride semiconductor device 1 need not include third underlayer 28.

Moreover, third underlayer 28 may have the function of supplying electrons to a channel formed at the interface between electron transport layer 42 and electron supply layer 44. For instance, third underlayer 28 has a larger band gap than electron supply layer 44.

Gate opening 30 is an example of a trench provided in first nitride semiconductor layer 20. Gate opening 30 penetrates first underlayer 24 and reaches drift layer 22. Specifically, gate opening 30 extends from the top surface of third underlayer 28, penetrates third underlayer 28, second underlayer 26, and first underlayer 24 in the stated order, and reaches drift layer 22. Bottom portion 30a of gate opening 30 is a portion of the top surface of drift layer 22. In the embodiment, as illustrated in FIG. 1, bottom portion 30a of gate opening 30 is below the interface between drift layer 22 and first underlayer 24.

In the embodiment, the opening area of gate opening 30 increases in the direction away from substrate 10. Specifically, sidewall portion 30b of gate opening 30 is inclined. A cross-sectional shape of gate opening 30 is, for example, an inverted trapezoid, more specifically, an inverted isosceles trapezoid.

Second nitride semiconductor layer 40 is provided to cover the trench provided in first nitride semiconductor layer 20. Specifically, second nitride semiconductor layer 40 is provided to cover gate opening 30. Second nitride semiconductor layer 40 is a regrowth layer formed by regrowth after crystal growth for forming first nitride semiconductor layer 20. As illustrated in FIG. 1, second nitride semiconductor layer 40 includes a layered structure including electron transport layer 42 and electron supply layer 44. Moreover, source opening 50 is provided in second nitride semiconductor layer 40.

Electron transport layer 42 is a first regrowth layer including a portion above first underlayer 24 and a portion provided along the inner surface of gate opening 30. Specifically, electron transport layer 42 is formed to cover each of the top surface of third underlayer 28 and sidewall portion 30b and bottom portion 30a of gate opening 30. For instance, electron transport layer 42 is formed of GaN having a thickness of 100 nm.

Electron transport layer 42 is in contact with drift layer 22 on bottom portion 30a of gate opening 30. At sidewall portion 30b of gate opening 30, electron transport layer 42 is in contact with the side surface of each of first underlayer 24, second underlayer 26, and third underlayer 28. Furthermore, electron transport layer 42 is in contact with the top surface of third underlayer 28.

Electron transport layer 42 has a channel. Specifically, two-dimensional electron gas is generated near the interface between electron transport layer 42 and electron supply layer 44. Two-dimensional electron gas functions as a channel of electron transport layer 42. Although electron transport layer 42 is an undoped layer, it may be doped with, for example, Si to become n-type.

Moreover, although not illustrated in the figures, in the embodiment, as a second regrowth layer, an AlN film having a thickness of around 1 nm is provided between electron transport layer 42 and electron supply layer 44. The AlN film can suppress alloy scattering and improve the channel mobility. It should be noted that the AlN film need not be provided, and electron transport layer 42 and electron supply layer 44 may be directly in contact with each other.

Electron supply layer 44 is a third regrowth layer including a portion above first underlayer 24 and a portion provided along the inner surface of gate opening 30. It should be noted that electron transport layer 42 and electron supply layer 44 are provided in the stated order from the side on which substrate 10 is present. Electron supply layer 44 is, for example, an undoped Al_{0.2}Ga_{0.8}N film having a thickness of 50 nm.

Electron supply layer 44 supplies electrons to the channel formed in electron transport layer 42. It should be noted that as described above, in the embodiment, third underlayer 28 also has the function of supplying electrons. Although both electron supply layer 44 and third underlayer 28 are formed of AlGaN, the Al composition ratio at this time is not particularly limited. For instance, the Al composition ratio of electron supply layer 44 may be 20%, and the Al composition ratio of third underlayer 28 may be 25%. It should be noted that the Al composition ratio indicates the ratio of the Al atoms out of one or more elements other than nitrogen among the elements contained in the nitride semiconductor.

Source opening 50 is an example of an opening penetrating second nitride semiconductor layer 40. Specifically, source opening 50 penetrates electron supply layer 44 and electron transport layer 42 at a location away from gate electrode 62. More specifically, source opening 50 penetrates electron supply layer 44, electron transport layer 42, third underlayer 28, and second underlayer 26 in the stated order, and reaches first underlayer 24. In the embodiment, as illustrated in FIG. 1, bottom portion 50a of source opening 50 is a portion of the top surface of first underlayer 24. Bottom portion 50a is below the interface between first underlayer 24 and second underlayer 26. In a plan view, source opening 50 is spaced apart from gate opening 30.

As illustrated in FIG. 1, source opening 50 is formed with an approximately uniform opening area. Specifically, sidewall portion 50b of source opening 50 is approximately parallel to a thickness direction of substrate 10. For instance, source opening 50 has a rectangular cross-sectional shape. Alternatively, as with gate opening 30, source opening 50 may have an inverted-trapezoid cross-sectional shape.

Threshold control layer 60 is a fourth regrowth layer provided between gate electrode 62 and electron supply layer 44. Threshold control layer 60 is provided on electron supply layer 44 and is in contact with electron supply layer 44 and gate electrode 62. Threshold control layer 60 is, for example, a nitride semiconductor layer made of p-type Al_{0.2}Ga_{0.8}N with a thickness of 100 nm and a carrier concentration of 1×10¹⁷ cm⁻³.

Threshold control layer 60 increases the electric potential of the conduction band edge of a channel portion. This can make the threshold voltage of nitride semiconductor device 1 large. Thus, nitride semiconductor device 1 can be embodied as a normally-off FET.

It should be noted that threshold control layer 60 may be an insulator film, such as a silicon dioxide film or a silicon nitride film. Moreover, threshold control layer 60 need not be provided.

Gate electrode 62 is above second nitride semiconductor layer 40, and is provided to overlap with at least a portion of gate opening 30 in a plan view of substrate 10. In the embodiment, gate electrode 62, having an approximately uniform thickness and a shape conforming to the top surface of threshold control layer 60, is formed in contact with the top surface of threshold control layer 60. It should be noted that if threshold control layer 60 is not provided, gate electrode 62 is provided in contact with the top surface of electron supply layer 44.

Gate electrode 62 is formed using a conductive material, such as metal. For instance, gate electrode 62 is formed using palladium (Pd). It should be noted that a material to form a Schottky contact with an n-type semiconductor can be used as a material of gate electrode 62. For instance, a nickel (Ni)-based material, tungsten silicide (WSi), gold (Au), and so forth can be used.

Gate electrode 62 is spaced apart from source electrode 64 in the plan view to avoid contact with source electrode 64. Specifically, as illustrated in FIG. 2, in the plan view, gate electrode 62 surrounds source electrode 64. More specifically, gate electrode 62 is formed into a shape of a single plate with openings corresponding to source electrodes 64.

Source electrode 64 is above substrate 10 and is spaced apart from gate electrode 62. In the embodiment, source electrode 64 is provided in source opening 50. Specifically, source electrode 64 is provided to fill source opening 50. Source electrode 64 is in contact with first underlayer 24 on bottom portion 50a of source opening 50. Specifically, source electrode 64 is in contact with the end faces of electron supply layer 44, electron transport layer 42, third underlayer 28, and second underlayer 26. Source electrode 64 is in ohmic contact with electron transport layer 42 and electron supply layer 44.

Source electrode 64 is formed using a conductive material, such as metal. A material, such as Ti/Al, to form an ohmic contact with an n-type semiconductor layer can be used as a material of source electrode 64.

Since source electrode 64 is connected to first underlayer 24, it is possible to fix the electric potential of first underlayer 24, which can stabilize operation of nitride semiconductor device 1. It should be noted that Al contained in source electrode 64 forms a Schottky contact with first underlayer 24 made of a p-type nitride semiconductor. Thus, a lower portion of source electrode 64 may include a large-work-function metal material, such as Pd or Ni, that has low contact resistance to the p-type nitride semiconductor. This can further stabilize the electric potential of first underlayer 24.

Drain electrode 66 is provided below substrate 10. Specifically, drain electrode 66 is provided in contact with second main surface 10b of substrate 10. Drain electrode 66 is formed using a conductive material, such as metal. As with the material of source electrode 64, a material, such as Ti/Al, to form an ohmic contact with an n-type semiconductor layer can be used as a material of drain electrode 66.

Insulation layer 70 is provided to electrically insulate gate electrode 62 from source electrode pad 74 and source electrode 64. Insulation layer 70 is, for example, a silicon dioxide film or a silicon nitride film.

Gate electrode pad 72 is electrically connected to gate electrode 62. Gate electrode pad 72 is provided above gate electrode 62, for example. In the embodiment, gate electrode 62 is formed into a plate-like shape. As such, as illustrated in FIG. 2, gate electrode pad 72 is formed only in a part of an area in a plan view of nitride semiconductor device 1. A power supply for controlling gate electrode 62 is connected externally to gate electrode pad 72.

Source electrode pad 74 is electrically connected to each of source electrodes 64. Source electrode pad 74 is above source electrodes 64. In the embodiment, each of source electrodes 64 is island-shaped. Thus, in the plan view of nitride semiconductor device 1, source electrode pad 74 is provided in most of the area except for gate electrode pad 72 to cover each of source electrodes 64.

As described above, in nitride semiconductor device 1 according to the embodiment, the interface between electron transport layer 42 and electron supply layer 44 serves as an AlGaN/GaN heterointerface. Thus, two-dimensional electron gas is generated in electron transport layer 42, thereby forming a channel. The two-dimensional electron gas has a high carrier concentration, which increases the channel mobility and decreases the on-resistance.

### Plan View Layout

A plan view layout of nitride semiconductor device 1 according to the embodiment is described with reference to FIG. 2.

As illustrated in FIG. 2, nitride semiconductor device 1 includes a plurality of source electrodes 64 and a plurality of gate openings 30. It should be noted that in FIG. 2, the outlines of gate opening 30 are indicated by dashed lines. The dashed lines illustrated in FIG. 2 correspond to the upper end portions of gate opening 30, that is, the upper end portions of sidewall portion 30b.

It should be noted that in the embodiment, an m-axis direction and an a-axis direction of GaN of substrate 10 are respectively assigned an X-axis direction and a Y-axis direction in the figures. The m-axis direction is expressed as [1-100], and the a-axis direction is expressed as [11-20]. Moreover, a c-axis direction is expressed as [0001]. The c-axis direction and a Z-axis direction do not coincide, but they intersect at a predetermined angle. The predetermined angle corresponds to the off-angle of substrate 10.

The off-angle refers to the angle that the c-plane of GaN, or (0001) plane, forms with first main surface 10a of substrate 10. The off-angle is, for example, greater than 0 degrees and less than or equal to 5 degrees. The off-angle may be greater than or equal to 0.1 degrees. The off-angle may be less than or equal to 1 degree or 0.5 degrees.

Source electrodes 64 are elongated in a first direction. In the embodiment, the first direction corresponds to the Y-axis direction illustrated in FIG. 2, and corresponds to the a-axis direction of GaN of substrate 10. It should be noted that the first direction, that is, a longitudinal direction may be a direction intersecting the a-axis direction. Here, the angle formed by the first direction and the a-axis direction may be, for example, less than or equal to 1 degree.

Source electrode 64 is linearly elongated in the a-axis direction. A plan-view shape of source electrode 64 is a sufficiently long rectangular shape where for instance the length in the longitudinal direction is at least 10 times that in a transverse direction. The plan-view shapes of source electrodes 64 are approximately the same. It should be noted that in an area where gate electrode pad 72 is provided, source electrodes 64 are shorter to avoid contact with gate electrode pad 72.

Source electrodes 64 are arranged in a direction orthogonal to the a-axis direction in which each source electrode 64 extends, that is, source electrodes 64 are arranged in the m-axis direction. Furthermore, source electrodes 64 are arranged in the a-axis direction. In the example illustrated in FIG. 2, nitride semiconductor device 1 includes a total of 18 source electrodes 64 arranged in a matrix with two rows and nine columns. It should be noted that two source electrodes 64 arranged in the a-axis direction may be configured as a single long source electrode.

Gate electrode 62 surrounds source electrode 64 in the plan view. Specifically, gate electrode 62 is a single conductive layer provided across the entire surface of substrate 10, and openings are provided in areas corresponding to source electrodes 64. Because of the openings provided in gate electrode 62, source electrodes 64 are exposed to be electrically connected to source electrode pad 74.

In the plan view, gate opening 30 is elongated in the a-axis direction, and has an O-shape or a racetrack shape. Specifically, as illustrated in FIG. 2, gate opening 30 includes two linear portions: linear portion 31 and linear portion 32 and two connection portions: connection portion 33 and connection portion 34.

In a plan view of first main surface 10a of substrate 10, two linear portions 31 and 32 linearly extend in the first direction (the Y-axis direction) with source electrode 64 interposed therebetween. Specifically, two linear portions 31 and 32 are parallel to each other, and linearly extend in the a-axis direction of GaN.

Connection portion 33 is an example of a first connection portion of an arch shape connecting a first end portion of linear portion 31 and a first end portion of linear portion 32. The first end portions are end portions on the positive side in the Y-axis direction of linear portions 31 and 32. Connection portion 33 surrounds one end portion in the longitudinal direction of source electrode 64 (an end portion on the positive side in the Y-axis direction).

Connection portion 34 is an example of a second connection portion of an arch shape connecting a second end portion of linear portion 31 and a second end portion of linear portion 32. The second end portion is the opposite end portion of the first end portion, and an end portion on the negative side in the Y-axis direction of each of linear portions 31 and 32. Connection portion 34 surrounds the other end portion in the longitudinal direction of source electrode 64 (an end portion on the negative side in the Y-axis direction).

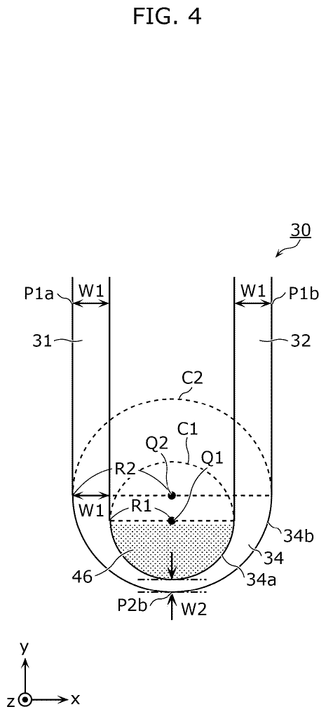

It should be noted that the arch shape means a shape that is convex toward either the positive side or the negative side of the Y-axis direction. For instance, both the outline on the inner-circumferential side and the outline on the outer-circumferential side of connection portion 33 are convex toward the positive side of the Y-axis direction. For instance, both the outline on the inner-circumferential side and the outline on the outer-circumferential side of connection portion 34 are convex toward the negative side of the Y-axis direction. In the embodiment, connection portion 33 is the shape of connection portion 34 reflected about the X-axis direction. The shape of connection portion 34 is described later with reference to FIG. 4.

Gate openings 30 are arranged in a direction orthogonal to the direction in which each of linear portions 31 and 32 extends (specifically, the a-axis direction), that is, gate openings 30 are arranged in the m-axis direction. In the example illustrated in FIG. 2, five gate openings 30 are provided. Linear portions 31 and 32 of gate openings 30 and source electrodes 64 are provided so that linear portion 31, source electrode 64, and linear portion 32 are arranged in a repeating sequence in the m-axis direction.

In the embodiment, since a longitudinal direction of gate opening 30 is the a-axis direction, most of sidewall portion 30b of gate opening 30 can be used as the m-plane of GaN. This suppresses GaN crystal facet formation on sidewall portion 30b of gate opening 30. Thus, it is possible to achieve good electrode contact to gate electrode 62 and decrease the resistance of a channel along sidewall portion 30b.

It should be noted that the longitudinal direction of gate opening 30 need not necessarily be the a-axis direction. For instance, the longitudinal direction of gate opening 30 may be the m-axis direction. In this case, the surfaces of the nitride semiconductor layers formed on substrate 10 by crystal growth exhibit good flatness. Thus, the stability of a process, such as exposure, improves, which can make nitride semiconductor device 1 with high quality and increase yields.

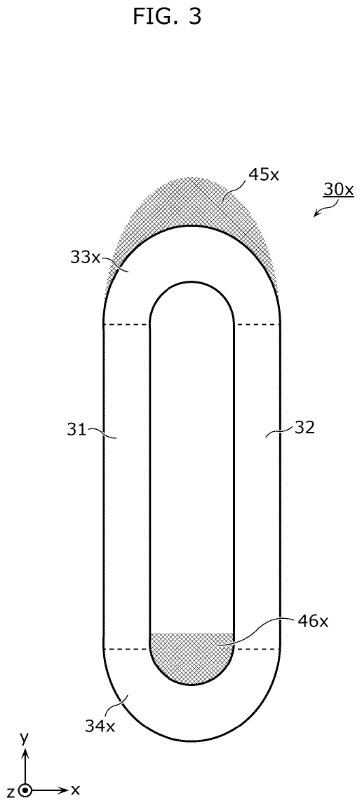

In nitride semiconductor device 1 according to the embodiment, abnormal growth caused by the off-angle of substrate 10 is described with reference to FIG. 3. FIG. 3 is a plan view for explaining abnormal growth caused by the off-angle of a substrate in a nitride semiconductor device according to a comparison example. FIG. 3 illustrates only gate opening 30x among the elements of the nitride semiconductor device according to the comparison example. It should be noted that the nitride semiconductor device according to the comparison example differs from nitride semiconductor device 1 illustrated in FIGS. 1 and 2 only in the shape of the gate opening. As illustrated in FIG. 3, gate opening 30x according to the comparison example is uniform in the width.

In the embodiment, first main surface 10a of substrate 10 is inclined with an off-angle in the Y-axis direction (specifically, the a-axis direction). Specifically, first main surface 10a of substrate 10 has a downward inclination in a [11-20] direction relative to the c-plane of GaN. The off-angle at this time is, for example, around 0.4 degrees. In the plan view in FIG. 3, first main surface 10a is higher on the negative side in the Y-axis direction, and first main surface 10a is lower on the positive side in the Y-axis direction. It should be noted that regarding high and low of first main surface 10a, the positive side in the Z-axis direction is defined as high, and the negative side of the Z-axis direction is defined as low.

Since first main surface 10a of substrate 10 has an off-angle, crystal growth onto first main surface 10a is facilitated, and drift layer 22 with superior film properties can be formed. Meanwhile, the off-angle causes abnormal growth in a regrowth layer formed to cover gate opening 30x.

A raw material supplied in a regrowth process tends to move from a high position of the slope toward a low position in an off-direction. For instance, a portion of a raw material supplied to area 46x flows to a lower position of the slope (toward the positive side of the Y-axis direction). Meanwhile, connection portion 34x of gate opening 30x is formed at a higher position of the slope than area 46x, that is, on the negative side in the Y-axis direction relative to area 46x. Thus, a raw material does not enter area 46x from gate opening 30x. As a result, a raw material that can contribute to the growth in area 46x is decreased, which results in abnormal growth in area 46x, in which the film thickness of the regrowth layer is thin.

Moreover, since a reduced amount of a raw material is supplied from connection portion 33x to area 45x adjacent to connection portion 33x, the film thickness of the regrowth layer in area 45x is thin. That is, abnormal growth of the regrowth layer is also caused in area 45x as it is in area 46x.

In the embodiment, second nitride semiconductor layer 40 and threshold control layer 60 are formed as regrowth layers. Second nitride semiconductor layer 40 includes a channel, and threshold control layer 60 controls the channel. Thus, the properties of nitride semiconductor device 1 deteriorate with a decrease in the film thickness of at least one of second nitride semiconductor layer 40 or threshold control layer 60. Thus, it is not preferable to form, for example, source electrode 64 in area 45x and area 46x with abnormal growth. Avoiding using area 45x and area 46x as effective areas of a field-effect transistor (FET) leads to a decrease in the effective area where it operates as the FET.

As such, in the embodiment, to reduce areas with abnormal growth, the shape of gate opening 30 varies depending on the locations thereof. FIG. 2 illustrates location P1a, location P1b, location P2a, and location P2b as characteristic locations of gate opening 30.

Each of locations P1a and P1b is a location where gate opening 30 extends in the first direction (the Y-axis direction) parallel to an off-direction of substrate 10. FIG. 2 illustrates virtual straight line VL1 extending in the second direction (the X-axis direction) orthogonal to the off-direction of substrate 10. Virtual straight line VL1 is an example of a first virtual straight line, and is a virtual straight line passing through the center in the plan view of one of source electrodes 64. The locations where virtual straight line VL1 and gate opening 30 intersect are locations P1a and P1b. Location P1a is included in linear portion 31. Location P1b is included in linear portion 32.

Each of locations P2a and P2b is a location where gate opening 30 extends in the second direction (the X-axis direction) perpendicular to the off-direction of substrate 10. FIG. 2 illustrates virtual straight line VL2 extending in the first direction (the Y-axis direction) parallel to the off-direction of substrate 10. Virtual straight line VL2 is an example of a second virtual straight line, and is a virtual straight line passing through the center in the plan view of one of source electrodes 64. The locations where virtual straight line VL2 and gate opening 30 intersect are locations P2a and P2b. Location P2a is included in connection portion 33. Location P2b is included in connection portion 34.

It should be noted that FIG. 2 illustrates virtual straight lines VL1 and VL2 passing through source electrode 64 on the lower left (the source electrode located on the most negative side of each of the X and Y axes) among source electrodes 64. However, the center of different source electrode 64 may be used as a reference.

In the embodiment, the cross-sectional area, orthogonal to the X-axis direction, of gate opening 30 at each of locations P2a and P2b is smaller than the cross-sectional area, orthogonal to the Y-axis direction, of gate opening 30 at each of locations P1a and P1b. Specifically, the width of gate opening 30 at each of locations P2a and P2b is less than that of gate opening 30 at each of locations P1a and P1b. More specifically, the width of each of connection portions 33 and 34 of gate opening 30 is less than that of each of linear portions 31 and 32 of gate opening 30.

FIG. 4 is an enlarged plan view illustrating a shape of gate opening 30 in area IV in FIG. 2. It should be noted that FIG. 4 illustrates only gate opening 30 among the elements of nitride semiconductor device 1. Specifically, the outlines of the upper ends of gate opening 30 are indicated by solid lines.

At least a part of outline 34a on the inner-circumferential side of connection portion 34 and at least a part of outline 34b on the outer-circumferential side of connection portion 34 each follow a circular arc or an elliptical arc. In the embodiment, at least a part of outline 34a and at least a part of outline 34b each coincide with a circular arc or an elliptical arc.

Specifically, as illustrated in FIG. 4, at least a part of outline 34a coincides with the arc of circle C1 with point Q1 as the center and radius R1. For instance, at least a part of outline 34a coincides with half the entire circumference of circle C1, that is, a semicircular arc. For instance, the diameter (2×R1) of circle C1 is equal to the distance between two adjacent linear portions 31 and 32.

At least a part of outline 34b coincides with the arc of circle C2 with point Q2 as the center and radius R2 (R2>R1). For instance, at least a part of outline 34b coincides with half the entire circumference of circle C2, that is, a semicircular arc.

The width of gate opening 30 is the largest in each of linear portions 31 and 32, and the value of the width is W1=R2−R1. The width of gate opening 30 decreases from the position where linear portion 31 and connection portion 34 are connected and the position where linear portion 32 and connection portion 34 are connected. The width of gate opening 30 is the narrowest in a tip portion (location P2b) of gate opening 30. Width W2 of gate opening 30 at this time is W2<R2−R1=d1. That is, the width of connection portion 34 monotonously increases from location P2b to end portions of linear portions 31 and 32 (the end portions on the negative side in the Y-axis direction). The rate of an increase in the width may be constant or vary. Moreover, connection portion 34 may include a segment where the width does not change.

For the configuration, in connection portion 34 in the regrowth process, not only a raw material directly supplied to connection portion 34 but also a raw material supplied in the off-direction to connection portion 34 are embedded into connection portion 34. Embedding proceeds quickly for connection portion 34 with a small width. When embedding of connection portion 34 completes, the raw materials are supplied from connection portion 34 to area 46, which suppresses a raw material shortage in area 46. An abnormal growth area is reduced by suppressing the decrease in the film thickness in area 46, which results in a larger effective area as an FET.

As with connection portion 34, the width of connection portion 33 monotonously increases from location P2a to end portions of linear portions 31 and 32 (the end portions on the positive side in the Y-axis direction). The rate of an increase in the width may be constant or vary. Moreover, connection portion 33 may include a segment where the width does not change. By doing so, a raw material shortage is suppressed in an area adjacent to the outer-circumferential side of connection portion 33, which can reduce an abnormal growth area.

As described above, in the embodiment, nitride semiconductor device 1 with suppressed abnormal growth can be embodied. The reduction of the abnormal growth area can increase the FET effective area, which makes it possible to achieve, for example, higher current and higher breakdown voltage.

Moreover, in the embodiment, as a non-limiting example, embedding is expedited by reducing the width of each of connection portions 33 and 34. At least one of connection portion 33 or 34 may be made shallower in depth. It should be noted that the depth is the distance from the upper end of gate opening 30 to bottom portion 30a in the Z-axis direction. The gate opening with a depth that varies depending on the locations can be formed by, for example, multi-step etching. The cross-sectional areas of connection portions 33 and 34 may be reduced by a method different from the method of making the width or depth vary.

### VARIATION

Next, a variation of the embodiment is described.

The variation differs from the above embodiment in the plan-view shape of the gate opening. Hereinafter, the description focuses on differences from the embodiment. In the variation, parts not particularly explained are the same as those described in the embodiment.

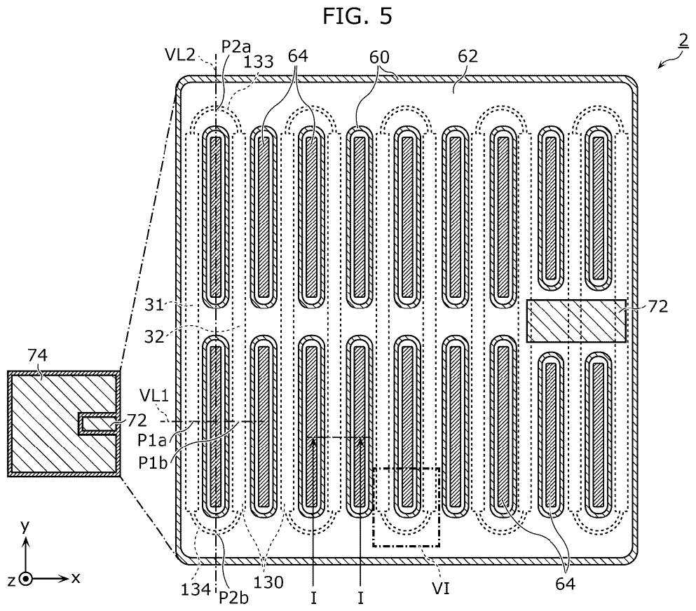

FIG. 5 is a plan view illustrating a plan view layout of nitride semiconductor device 2 according to the variation. As illustrated in FIG. 5, nitride semiconductor device 2 differs from nitride semiconductor device 1 according to the embodiment in terms of including gate opening 130 instead of gate opening 30. Gate opening 130 has a plan view shape different from that of gate opening 30, and has the same cross-sectional shape as gate opening 30. For instance, the cross-section taken along I-I line illustrated in FIG. 5 is the same as that of nitride semiconductor device 1 illustrated in FIG. 1.

Gate opening 130 according to the variation includes two linear portions: linear portion 31 and linear portion 32 and two connection portions: connection portion 133 and connection portion 134. The plan view shapes of connection portions 133 and 134 differ from those of connection portions 33 and 34 of gate opening 30.

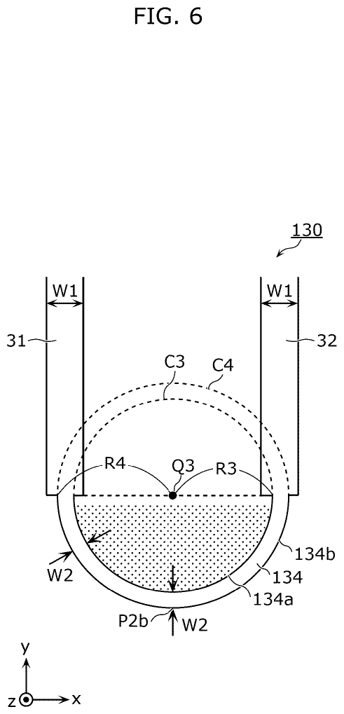

As with the embodiment described above, connection portion 133 is an example of a first connection portion of an arch shape connecting first end portions of two linear portions 31 and 32 (end portions on the positive side in the Y-axis direction). Connection portion 134 is an example of a second connection portion connecting second end portions of two linear portions 31 and 32 (end portions on the negative side in the Y-axis direction). In the variation, each of connection portions 133 and 134 has a uniform width. Connection portion 133 is the shape of connection portion 134 reflected about the X-axis direction. The shape of connection portion 134 is described below with reference to FIG. 6.

FIG. 6 is an enlarged plan view illustrating a shape of gate opening 130 in area VI in FIG. 5. It should be noted that FIG. 6 illustrates only gate opening 130 among the elements of nitride semiconductor device 2. Specifically, the outlines of the upper ends of gate opening 130 are indicated by solid lines.

At least a part of outline 134a on the inner-circumferential side of connection portion 134 and at least a part of outline 134b on the outer-circumferential side of connection portion 134 each follow a circular arc or an elliptical arc. In the variation, at least a part of outline 134a and at least a part of outline 134b each coincide with a circular arc or an elliptical arc.

Specifically, as illustrated in FIG. 6, outline 134a coincides with the arc of circle C3 with point Q3 as the center and radius R3. For instance, outline 134a coincides with half the entire circumference of circle C3, that is, a semicircular arc.

Outline 134b coincides with the arc of circle C4 with point Q3 as the center and radius R4 (R4>R3). For instance, outline 134b coincides with half the entire circumference of circle C4, that is, a semicircular arc. Outline 134b and outline 134a are formed concentrically.

In the variation, the width of connection portion 134 is width W2 at location P2b, and is uniform. The width of gate opening 130 changes at the positions where connection portion 134 and linear portions 31 and 32 are connected. When the width of each of linear portions 31 and 32 is defined as W1, W2=R4−R3<W1.

Also in the variation, effects similar to those obtained in the embodiment can be obtained. That is, nitride semiconductor device 2 with suppressed abnormal growth can be embodied.

### Fabrication Method

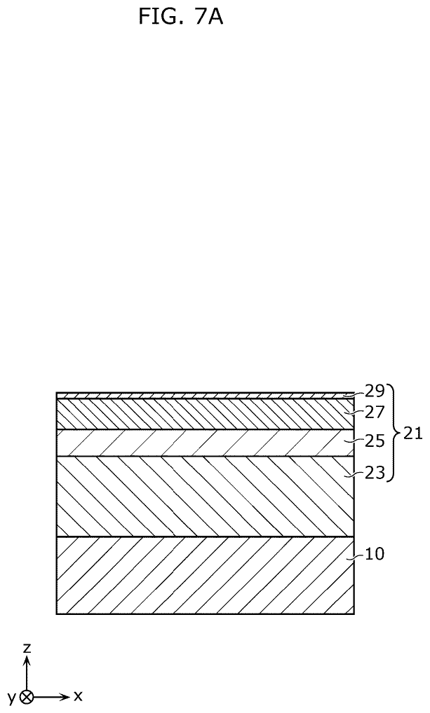

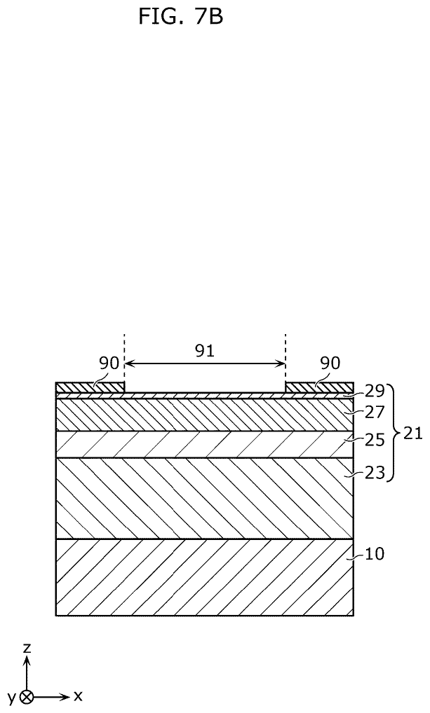

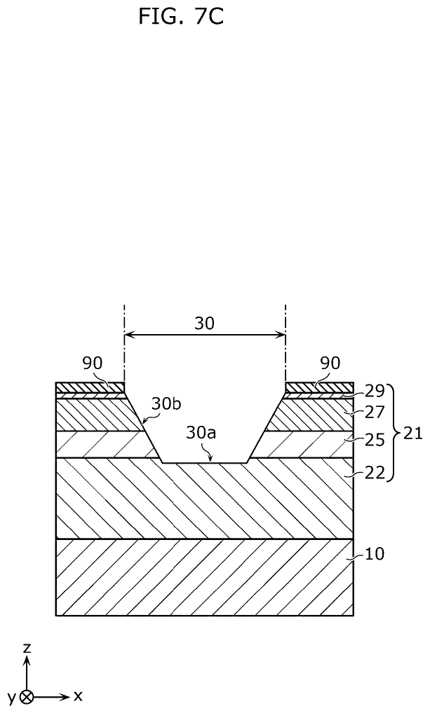

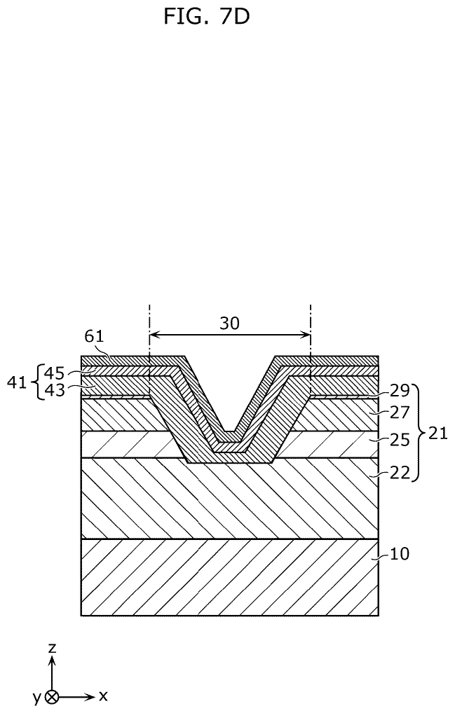

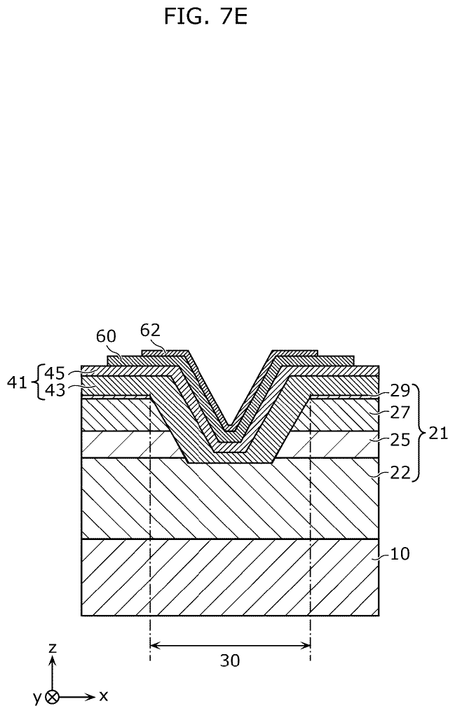

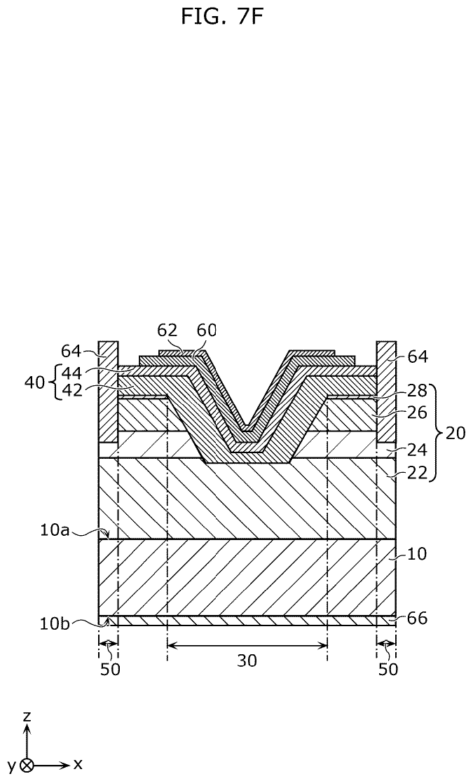

Next, a fabrication method for fabricating nitride semiconductor device 1 according to the embodiment is described with reference to FIGS. 7A to 7F. FIGS. 7A to 7F are cross-sectional views illustrating processes of the fabrication method for fabricating nitride semiconductor device 1 according to the embodiment.

Hereinafter, a case where the nitride semiconductor layers of nitride semiconductor device 1 are formed by metal organic vapor phase epitaxy (MOVPE) is described. It should be noted that a method for forming the nitride semiconductor layers is not limited to MOVPE. For instance, the nitride semiconductor layers may be formed by molecular beam epitaxy (MBE) or other epitaxial growth methods.

Moreover, an n-type nitride semiconductor is formed by adding, for example, silicon (Si). A p-type nitride semiconductor is formed by adding magnesium (Mg). It should be noted that an n-type impurity and a p-type impurity are not limited to the above examples.

First, n-type GaN substrate 10 whose first main surface 10a is the (0001) plane, that is, the c-plane is prepared. As illustrated in FIG. 7A, first nitride semiconductor film 21 is formed above first main surface 10a of substrate 10. Specifically, n-type GaN film 23 to which Si has been added as an n-type impurity, p-type GaN film 25 to which Mg has been added as a p-type impurity, undoped GaN film 27, and undoped AlGaN film 29 made of undoped Al_{0.2}Ga_{0.8}N are formed in the stated order. It should be noted that n-type GaN film 23, p-type GaN film 25, undoped GaN film 27, and undoped AlGaN film 29 are patterned into predetermined shapes to respectively become drift layer 22, first underlayer 24, second underlayer 26, and third underlayer 28 illustrated in FIG. 1.

The layers have thicknesses and carrier concentrations as described below, for example. N-type GaN film 23 has a thickness of 8μm and a carrier concentration of 1×10¹⁶ cm⁻³. P-type GaN film 25 has a thickness of 400 nm and a carrier concentration of 1×10¹⁷ cm⁻³. Undoped GaN film 27 has a thickness of 200 nm. Undoped AlGaN film 29 has a thickness of 20 nm. It should be noted that the above numerical values are mere examples.

Then, as illustrated in FIG. 7B, a resist is applied to undoped AlGaN film 29, and the applied resist is patterned by photolithography to form resist mask 90. Resist mask 90 is a mask for forming gate opening 30 and has opening 91 that conforms to the plan-view shape of gate opening 30.

Next, as illustrated in FIG. 7C, gate opening 30 is formed by dry etching. Gate opening 30 penetrates undoped AlGaN film 29, undoped GaN film 27, and p-type GaN film 25, and drift layer 22 (n-type GaN film 23) is exposed. Here, bottom portion 30a of gate opening 30 is parallel to first main surface 10a of substrate 10. Sidewall portion 30b of gate opening 30 is inclined relative to bottom portion 30a with a predetermined angle of inclination. The angle of inclination falls within the range from 20 degrees to 80 degrees, inclusive, for example.

After resist mask 90 is removed, as illustrated in FIG. 7D, second nitride semiconductor film 41 and p-type GaN film 61 are formed. Specifically, undoped GaN film 43, an undoped AlN film (not illustrated), undoped AlGaN film 45, and p-type GaN film 61 are formed in the stated order by MOVPE across the entire surface of gate opening 30 along the shape of gate opening 30. Undoped GaN film 43, undoped AlGaN film 45, and p-type GaN film 61 are patterned into predetermined shapes to respectively become electron transport layer 42, electron supply layer 44, and threshold control layer 60.

Regarding the thickness of each layer, undoped GaN film 43 has a thickness of 200 nm, the undoped AlN film has a thickness of 1 nm, undoped AlGaN film 45 has a thickness of 50 nm, and p-type GaN film 61 has a thickness of 200 nm. It should be noted that the above numerical values are mere examples.

Then, a gate metal film made of Pd is formed to cover gate opening 30 by, for example, vapor deposition or sputtering. As illustrated in FIG. 7E, gate electrode 62 is formed by patterning the formed gate metal film.

Furthermore, as illustrated in FIG. 7F, source opening 50 is formed at a location away from gate electrode 62. Specifically, as with gate opening 30, source opening 50 is formed by photolithography and dry etching, by making it penetrating p-type GaN film 61, undoped AlGaN film 45, undoped AlN film (not illustrated), undoped GaN film 43, undoped AlGaN film 29, and undoped GaN film 27, and exposing p-type GaN film 25. Threshold control layer 60, electron supply layer 44, electron transport layer 42, third underlayer 28, second underlayer 26, and first underlayer 24 are formed by respectively patterning p-type GaN film 61, undoped AlGaN film 45, undoped GaN film 43, undoped AlGaN film 29, undoped GaN film 27, and p-type GaN film 25.

Then, by a method, such as vapor deposition or sputtering, a source metal film made of Ti and Au is formed to fill source opening 50, and the formed source metal film is patterned into source electrode 64. Furthermore, a drain metal film made of Ti and Al is formed on second main surface 10b of substrate 10 by a method, such as vapor deposition or sputtering, and the formed drain metal film is patterned as necessary, thereby forming drain electrode 66.

Nitride semiconductor device 1 illustrated in FIG. 1 is formed through the above processes.

It should be noted that after gate electrode 62 and source electrode 64 are formed, insulation layer 70 is formed. Contact holes for exposing a portion of each of source electrodes 64 and a portion of gate electrode 62 are formed in the formed insulator film. Then, a metal film is formed and patterned to form gate electrode pad 72 and source electrode pad 74.

A fabrication method for fabricating nitride semiconductor device 2 according to the variation is similar to the above-mentioned method for fabricating nitride semiconductor device 1. As illustrated in FIG. 7B, in the process for forming resist mask 90 for forming gate opening 30, the shape of opening 91 of resist mask 90 may be conformed to that of gate opening 130.

### OTHER EMBODIMENTS

Although the nitride semiconductor device according to one or more aspects is described above based on the embodiment, the present disclosure is not limited to the embodiment. The scope of the present disclosure encompasses embodiments that result from modifications envisioned by those skilled in the art, as well as embodiments created by combining elements from different embodiments, provided that such embodiments remain within the scope of the present disclosure.

For instance, in the embodiment described above, as a non-limiting example, source opening 50 reaching first underlayer 24 is provided. For instance, source opening 50 may be an opening reaching electron transport layer 42. Moreover, source electrode 64 may be connected to electron transport layer 42, and need not be connected to first underlayer 24.

Moreover, as a non-limiting example, threshold control layer 60 and gate electrode 62 are provided to overlap bottom portion 30a of gate opening 30 in a plan view. In the plan view, threshold control layer 60 and gate electrode 62 may overlap sidewall portion 30b without overlapping bottom portion 30a. Alternatively, threshold control layer 60 and gate electrode 62 may be provided so as not to overlap gate opening 30 in the plan view. Specifically, threshold control layer 60 and gate electrode 62 may be located at a position that is outside gate opening 30 and overlaps the top surface of first nitride semiconductor layer 20 in the plan view. As with source electrode 64, threshold control layer 60 and gate electrode 62 may be disposed on both sides of gate opening 30 in such a manner that interposes gate opening 30 in the plan view. It should be noted that threshold control layer 60 need not be provided.

Here, in electron supply layer 44, a gate recess may be provided at a position overlapping gate electrode 62 in the plan view. The gate recess is a recessed portion provided in the top surface of electron supply layer 44. The thickness of electron supply layer 44 is small at the bottom of the gate recess, which makes it easier to suppress the occurrence of 2DEG during the off-time. This can easily achieve normally-off operation. Threshold control layer 60 is provided to cover the gate recess. When threshold control layer 60 is not provided, gate electrode 62 is provided to cover the gate recess.

Moreover, in this case, a first electrode electrically separated from threshold control layer 60 and gate electrode 62 may be provided at a position that is above second nitride semiconductor layer 40 and overlaps bottom portion 30a of gate opening 30 in the plan view. For instance, electric potential identical to electric potential supplied to source electrode 64 is supplied to the first electrode. For instance, a through hole may be provided in an insulation layer covering the first electrode, and a conductive via electrically connecting source electrode pad 74 and the first electrode may be provided. A p-type nitride semiconductor layer may be provided between the first electrode and second nitride semiconductor layer 40. The p-type nitride semiconductor layer is electrically separated from threshold control layer 60 and gate electrode 62. For instance, the first electrode and the p-type nitride semiconductor layer are in ohmic contact.

The above configuration enables electric field lines extending from drain electrode 66 to terminate in the first electrode and the p-type nitride semiconductor layer, which can decrease parasitic capacitance Cgd between the gate and drain. This can reduce the voltage and current rise and fall times, which in turn reduces switching loss. Moreover, a nitride semiconductor device capable of high-speed operation can be embodied. Even if a high-speed operation is performed, a total loss is suppressed. Thus, a low-loss power device can be embodied.

Moreover, for instance, the nitride semiconductor device need not be a vertical FET, but may be, for example, a horizontal FET or a diode. In this case, a trench provided in the first nitride semiconductor layer need not be gate opening 30. For instance, the trench may be provided as an isolation region.

Moreover, the trench need not be an annular trench. The trench may be made up of a plurality of trenches. For instance, the trench may include a first trench including a first location and a second trench including a second location. The first trench and the second trench may be connected to each other or intersect, and may be spaced apart from each other.

Moreover, the outline of a connection portion may be a polygonal line. When all polygonal vertices included in the polygonal line are on a circular arc or an elliptical arc, it can be regarded that the outline follows the circular arc or the elliptical arc.

Moreover, in the above embodiment, various modifications, replacement, addition, omission, and so forth can be made within the scope of the claims or equivalents thereof.

### INDUSTRIAL APPLICABILITY

The present disclosure is usable as, for example, a nitride semiconductor device with low leakage current and high breakdown voltage, and is usable as, for example, a power device used in a power supply circuit or the like of consumer equipment, such as a television.

1. A nitride semiconductor device comprising:
a substrate;
a first nitride semiconductor layer above the substrate; and
a second nitride semiconductor layer covering a trench provided in the first nitride semiconductor layer, wherein
when a location of the trench where the trench extends in a first direction parallel to an off-direction of the substrate is defined as a first location, and a location of the trench where the trench extends in a second direction perpendicular to the off-direction of the substrate is defined as a second location, a cross-sectional area, orthogonal to the second direction, of the trench at the second location is smaller than a cross-sectional area, orthogonal to the first direction, of the trench at the first location.

2. The nitride semiconductor device according to claim 1, wherein
a width of the trench at the second location is less than a width of the trench at the first location.

3. The nitride semiconductor device according to claim 2, wherein
the trench is an annular trench.

4. The nitride semiconductor device according to claim 1, wherein
the first nitride semiconductor layer includes:
a third nitride semiconductor layer of a first conductivity type; and
a fourth nitride semiconductor layer that is above the third nitride semiconductor layer, and has a second conductivity type with a polarity opposite to the first conductivity type.

5. The nitride semiconductor device according to claim 4, comprising:
a gate electrode above the second nitride semiconductor layer, the gate electrode overlapping the first location in a plan view of the substrate;
a source electrode that is above the substrate and is spaced apart from the gate electrode; and
a drain electrode below the substrate, wherein
the trench penetrates the fourth nitride semiconductor layer, and
the second nitride semiconductor layer is in contact with the third nitride semiconductor layer on a bottom of the trench.

6. The nitride semiconductor device according to claim 5, wherein
the source electrode is in contact with the fourth nitride semiconductor layer on a bottom of an opening penetrating the second nitride semiconductor layer.

7. The nitride semiconductor device according to claim 5, wherein
the source electrode is elongated in the first direction in the plan view of the substrate.

8. The nitride semiconductor device according to claim 7, wherein
the trench includes:
two linear portions interposing the source electrode and extending in the first direction;
a first connection portion of an arch shape connecting first end portions in the first direction respectively included in the two linear portions; and
a second connection portion of an arch shape connecting second end portions respectively included in the two linear portions that are on an opposite side from the first end portions,
each of the two linear portions includes the first location, and
each of the first connection portion and the second connection portion includes the second location.

9. The nitride semiconductor device according to claim 8, wherein
a width of the first connection portion monotonously increases from the second location included in the first connection portion to the first end portions, and
a width of the second connection portion monotonously increases from the second location included in the second connection portion to the second end portions.

10. The nitride semiconductor device according to claim 8, wherein
each of the first connection portion and the second connection portion has a uniform width.

11. The nitride semiconductor device according to claim 8, wherein
the first location is a location where the trench intersects a first virtual straight line passing through a center of the source electrode in the plan view of the substrate and extending in the second direction, and
the second location is a location where the trench intersects a second virtual straight line passing through the center of the source electrode in the plan view of the substrate and extending in the first direction.

12. The nitride semiconductor device according to claim 8, comprising:
three or more source electrodes each of which is the source electrode, wherein
two or more trenches each of which is the trench are arranged in the second direction,
the three or more source electrodes are arranged in the second direction, and
a corresponding one of the three or more source electrodes is disposed between adjacent trenches among the two or more trenches.

13. The nitride semiconductor device according to claim 1, wherein
the second nitride semiconductor layer includes a layered structure of a GaN layer and an AlGaN layer.
